(19) United States
(12) Patent Application Publication
(10) Pub. No.: US 2018/0261484 A1
(43) Pub. Date: Sep. 13, 2018

(54) PADDLE ASSEMBLY FOR HOLDING AN OBJECT

(71) Applicant: Verselus, LLC, Pleasanton, CA (US)

(72) Inventors: Christopher Martin, Livermore, CA (US); Troy Kreger, Livermore, CA (US); Neil Brumberger, Saratoga, CA (US); Philip Hobden, San Jose, CA (US)

(21) Appl. No.: 15/573,836

(22) PCT Filed: May 14, 2016
(86) PCT No.: PCT/US16/32571

§ 371 Date: Nov. 13, 2017

Related U.S. Application Data
(60) Provisional application No. 62/163,602, filed on May 19, 2015.

(51) Int. Cl. H01L 21/677; H01L 21/687

(52) U.S. Cl. CPC H01L 21/67766; B25J 15/0683; H01L 21/68707

(57) ABSTRACT

A paddle assembly is disclosed for holding an object during manufacture i.e., in a manufacturing environment. The paddle assembly comprises a first plate and a second plate, together forming a paddle having a longitudinal axis and defining a groove configured to engage the object on a peripheral edge thereof and seat the object along the longitudinal axis and a first pin between the first and second plates adjacent the groove, the first pin configured to align the object within the groove along the longitudinal axis.

### CROSS REFERENCE TO RELATED APPLICATIONS

The application claims priority to U.S. provisional application No. 62/163,602, filed May 19, 2015 entitled “Apparatus For Transporting Disks and Paddle Assemblies For Holding Disks” which is incorporated by reference herein.

### FIELD OF THE INVENTION

The present invention relates to a paddle assembly for holding an object.

### BACKGROUND OF THE INVENTION

The industry has developed a variety of grippers and vacuum paddles for the purpose of handling and transporting objects such as rigid disks (e.g., media, substrates, wafers and other round flat objects) in the various parts of the manufacturing process. Grippers/paddle weight and number of processing steps affect the precise control, speed, cost and overall processing efficiency. Unfortunately, the current grippers/paddles employed today cause significant contamination and misalignment for proper testing.

It would be desirous to provide improvements to grippers/paddles described above.

### SUMMARY OF THE INVENTION

Embodiments of a paddle for holding an object are disclosed.

In accordance with an embodiment of the disclosure, a paddle assembly for holding an object is disclosed. The paddle assembly comprising: a first plate and a second plate, together forming a paddle having a longitudinal axis and defining a groove configured to engage the object on a peripheral edge thereof and seat the object along the longitudinal axis, and a first pin between the first and second plates adjacent the groove, the first pin configured to align the object within the groove along the longitudinal axis.

In accordance with another embodiment of the disclosure, a paddle assembly is disclosed for holding an object having a peripheral edge that defines a radius of the object, the paddle assembly comprising: a first plate and a second plate opposing the first plate, the first plate and second plate together form a paddle having a longitudinal axis and configured to engage the object, wherein the first plate includes a chamfer edge and the second plate includes a chamfer edge, the chamfer edges of the first and second plates together define a groove configured to engage the object on the peripheral edge thereof and seat the object along the longitudinal axis; and a mount configured to mount the first and second plates to an end effector.

In accordance with another embodiment of the disclosure, a system is disclosed for processing disks during manufacture. The system comprises an apparatus for transporting a disk from one location to another location within a manufacturing environment, and a paddle assembly attached to the apparatus, the paddle assembly comprising a first plate and a second plate, together forming a paddle having a longitudinal axis and defining a groove configured to engage the object on a peripheral edge thereof and seat the object along the longitudinal axis, and a first pin between the first and second plates adjacent the groove, the first pin configured to align the object within the groove along the longitudinal axis.

In accordance with another embodiment of the disclosure, a system for processing disks during manufacture is disclosed. The system comprises an apparatus for transporting a disk from one location to another location; and a paddle assembly for hold a disk for transportation of the disk, wherein the paddle assembly comprising: a first plate and a second plate opposing the first plate, the first plate and second plate together form a paddle having a longitudinal axis and configured to engage the object, wherein the first plate includes a chamfer edge and the second plate includes a chamfer edge, the chamfer edges of the first and second plates together define a groove configured to hold the object on the peripheral edge thereof and seat the object along the longitudinal axis; and a mount configured to support the first and second plates.

In accordance with another embodiment of the disclosure, a paddle assembly is disclosed for holding an object during manufacture. The paddle assembly comprises a first plate and a second plate, together forming a paddle having a longitudinal axis and defining a groove configured to engage the object on a peripheral edge thereof and seat the object along the longitudinal axis, wherein the groove includes first and second inclined edges at least one of which engages the peripheral edge of the object.

### BRIEF DESCRIPTION OF THE DRAWINGS

Embodiments of the present disclosure are described herein with reference to the drawing figures.

FIG. 1 depicts a perspective view of an example system for processing disks during manufacture, wherein the system incorporates an apparatus for transporting the disks and paddle assemblies for holding the disks.

FIG. 2 depicts the system of FIG. 1 wherein the apparatus for transporting the disks and a paddle assembly is shown in an exploded configuration.

FIG. 3 depicts the system of FIG. 1 wherein the rotary union is shown in an exploded configuration.

FIG. 4 depicts a perspective view of the motor wrist drive of the apparatus for transporting the disks in FIG. 1.

FIG. 5 depicts a cross sectional view of the motor wrist drive taken along line 5-5 in FIG. 4.

FIG. 6 depicts an exploded unassembled view of the motor wrist drive of the apparatus for transporting the disks in FIG. 1.

FIG. 7 depicts a perspective view of the example paddle assembly of the system in FIG. 1 from the front.

FIG. 8 depicts a perspective view of the paddle assembly of the system in FIG. 1 from the rear.

FIG. 9 depicts an exploded unassembled view of the paddle assembly of the system in FIG. 1.

FIG. 10 depicts a cross sectional view of the paddle assembly taken along lines 10-10 in FIG. 8.

FIG. 11 depicts and enlarged sectional view of the paddle assembly of the system in FIG. 1 taken along line 11-11 in FIG. 10.

FIG. 12 depicts a cross sectional view of the paddle assembly of FIG. 1 along lines 12-12 in FIG. 10.

### DETAILED DESCRIPTION OF THE INVENTION

Embodiments of the present disclosure are described herein with reference to the drawing figures.

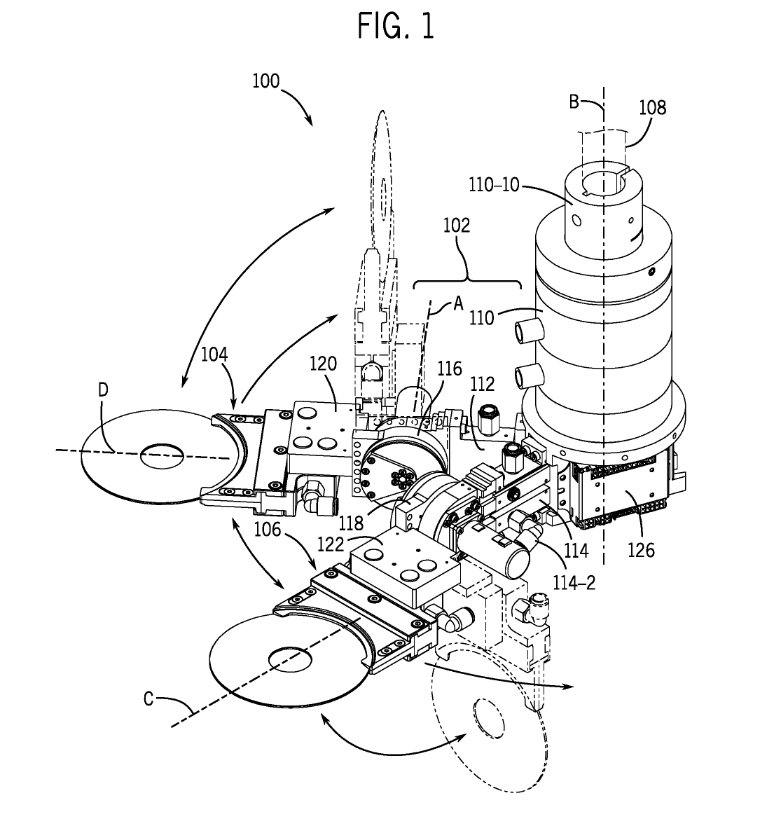

FIG. 1 depicts a perspective view of example system 100 for processing disks during manufacture, wherein system 100 comprises an apparatus 102 for (handling and) transporting disks (objects) and paddle assemblies 104,106 for holding the disks. In particular, apparatus 102 is configured to transport one or more disks from one location to another within a manufacturing environment (i.e., during manufacture) such as a workcell as known to those skilled in the art. The manufacturing environment includes testing and processing of the disks. One location, for example may be a cassette or carrier for storing disks or a spindle for performing testing on the disks. System 100 further includes robot unit 108 (dotted lines) that is configured to rotate apparatus 102 (and/or translate, i.e., move up and down) as described in more detail below.

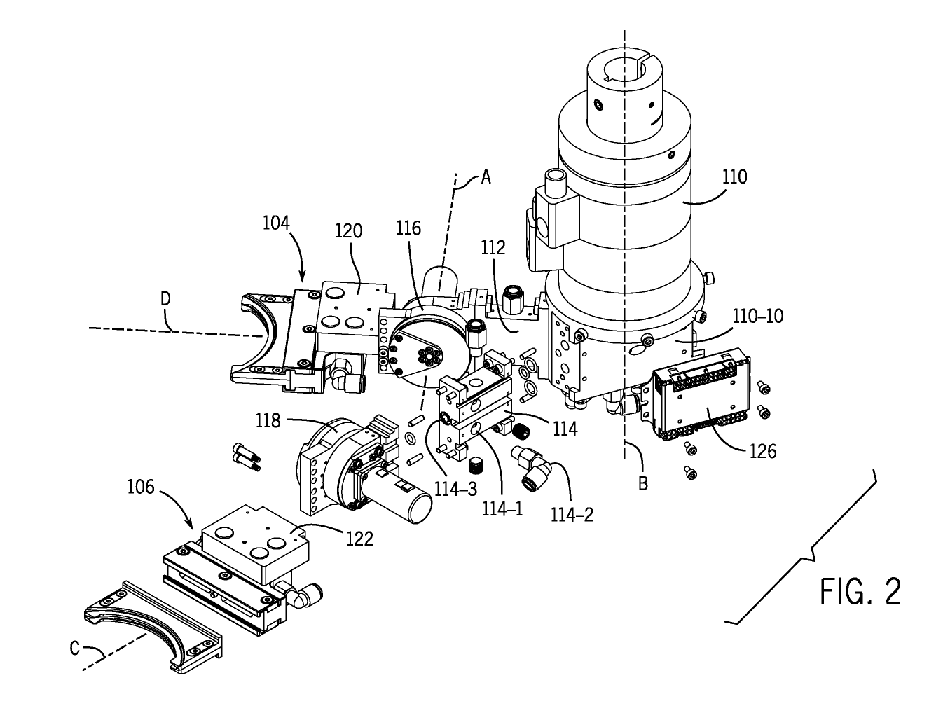

FIG. 2 depicts the system of FIG. 1 wherein apparatus 102 for transporting the disks and a paddle assembly is shown in an exploded configuration. Paddle assemblies 104, 106 are coupled to (engage with) apparatus 102 and robot unit 108 as described in more detail below. As known to those skilled in the art, disks are storage mechanisms where data are recorded (e.g., hard disk drives or HDD). Disks include media, substrates, wafers and other round flat objects known to those skilled in the art.

Apparatus 102 is an end effector 102 that comprises rotary union 110 (may also be referred to as rotary unit 110), ported arms 112, 114 (may also be referred to as arms 112,114), motor wrist drives 116, 118, off axis compliance, paddle mounting and adjustment blocks 120, 122 (may also be referred to as blocks 120,122) and motor drive controllers 124,126. (Motor wrist drives 116,118 may also be referred to as motor drives, drives or motor and sensor assemblies 116,118.)

Rotary union 110 attaches to robot unit 108 and they have a longitudinal axis B, i.e., they extend along a longitudinal axis B. Rotary union 110 is configured to rotate axially around the longitudinal axis and/or translate longitudinally along the longitudinal axis B in response to robot unit 108 as known to those skilled in the art. Rotary union 110 includes a main frame 110-10 integral to rotary union 110 that is attached to robot unit 108. Ported arms 112,114 are mounted to the base of main frame 110-10 and motor drive controllers 124,126 are also mounted to main frame 110-10. Ported arms 112,114 and motor drive controllers 124,126 are bolted to main frame 110-10. Main frame 110-10 is intended to deliver the vacuum and electrical services to the other parts of end effector 102. In this embodiment, rotary union 110 (including main frame 110-10) is integral to the overall structure of end effector 102. Importantly, rotary union 110 provides structural support to ported arms 112,114, motor wrist drives 116,118 and paddle assemblies 104,106, while at the same time serving as the direct mechanical interface to robot unit 108. Rotary union 110 is described in more detail below.

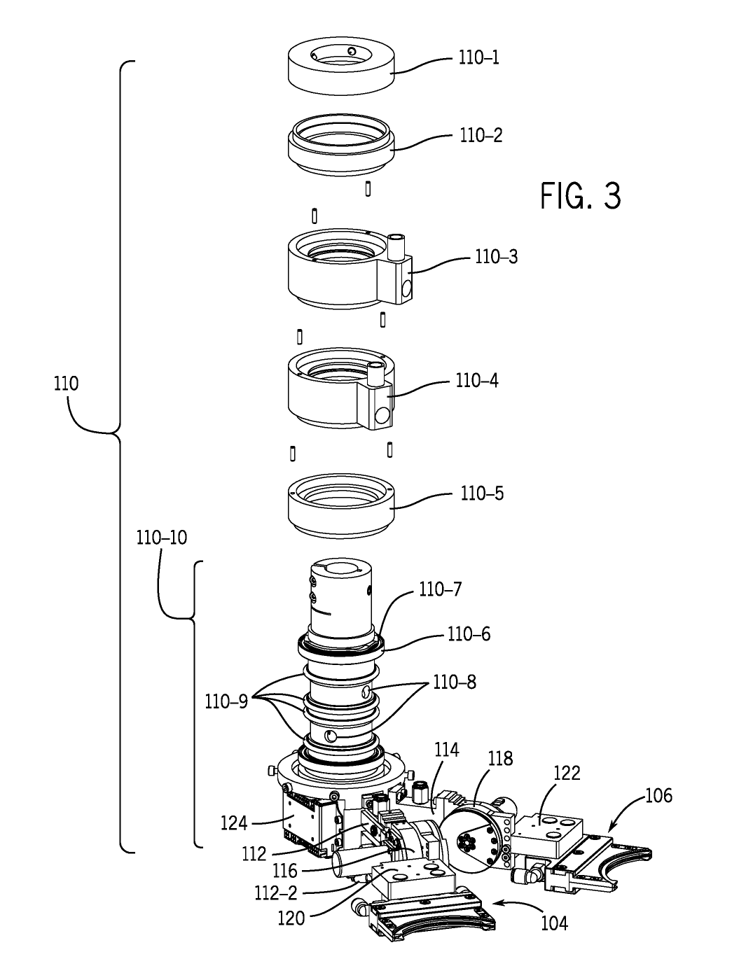

Ported arms 112, 114 are attached to rotary union 110 and provide the mounts for the motor wrist drives 116,118 and paddle assemblies 104,106, respectively. Ported arms 112, 114 each have a longitudinal axis (C, D), i.e., extends along a longitudinal axis and both are located in the same (horizontal) plane with respect to the longitudinal axis B of rotary union 110. Those skilled in the art know however that this plane may be oriented at a different angle with the respect to rotary union 110 to achieve desired results. Drives 116, 118 and ported arms 112, 114 are oriented to form an angle with respect to each other. That is, the longitudinal axes C and D of the ported arms 112, 114 intersect at the rotary union to form such angle. This angle is preferably an acute angle between 30 to 60 degrees or a reflex angle (i.e., angle greater than 180 degrees but less than 360 degrees), but those skilled in the art know that any angle may be used to achieve desired results. Arm 114 incorporates a vacuum channel to provide scavenging vacuum (not shown). Arm 114 also incorporates vacuum porting 114-1 and vacuum pipe 114-2 to provide process vacuum to paddle assemblies 104,106 as known to those skilled in the art. Arm 112 similarly includes a vacuum channel, vacuum porting and vacuum tubing 112-1 but they are not shown in FIGS. 1-2. Vacuum pipe 112-1 is depicted in FIG. 3.

Motor wrist drives 116,118 each include a pitch axis electrical motor (described below) intended to rotate a motor output shaft (described below) axially (around axis A), thereby causing a respective attached paddle assembly to pitch or pivot (move) up or down with respect to an arm and/or drive as shown (i.e., with respect to the longitudinal axis thereof). In the event that the arm and/or drive are oriented in a vertical direction for example, however, the paddle assembly may be pitched or moved side to side with respect to the arm. In sum, a drive may pitch or move a paddle assembly in one of two opposing directions depending on the position of the drive and/or the arm with respect to the rotary union). Motor wrist drives 116, 118 have first ends that are attached to first ends of ported arms 112,114, respectively. In this embodiment, motor wrist drives 116,118 are bolted directly to facing surfaces of ported arms 112,114, respectively. However, those skilled in the art know that assemblies 116,118 may be attached or mounted to ported arms 112,114 by other means. Alternatively, a motor wrist drive and arm may be one integral component (i.e., the motor wrist drive and arm may be one component).

Motor wrist drives 116,118 have second distal ends that are attached directly to off axis compliance, paddle mounting and adjustment blocks 120,122 respectively. In this embodiment, assemblies 116,118 are bolted directly to off axis compliance, paddle mounting and adjustment blocks 120,122, at different points (screw holes describe below) along vertical edge of pitch axis interfaces (described below) of the motor wrist drives 116,118, as shown to enable a user to adjust the pitch of paddle assemblies 104,106 with respect to the horizontal planes of motor wrist drives 116,118 (and ported arms 112,114), respectively. As described in more detail below, the horizontal plane of each motor wrist drive is positioned above the horizontal plane of each respective (attached) paddle assembly to enable a continuous position sensor (described below) of a motor wrist drive to sense (i.e., detect) forces or torques on the paddle assembly and thereby to adjust the programmed positions of paddle assembly during disk processing.

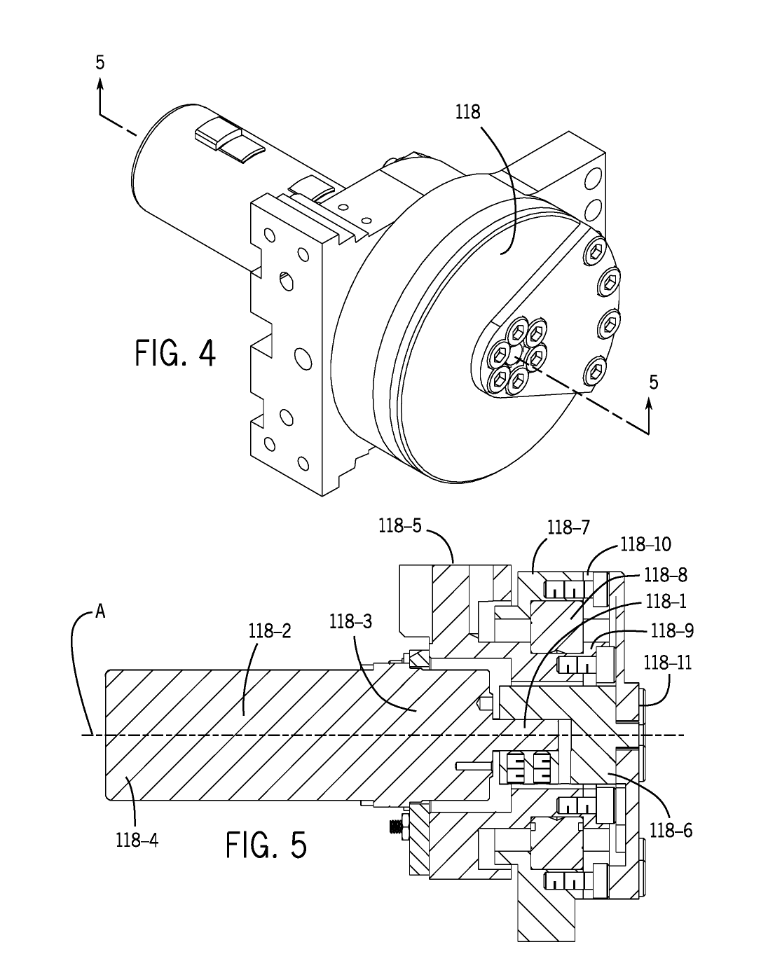

Each motor wrist drive 116,118 is configured to pitch a paddle assembly (104,106) in a precise, programmable motion within a 180 degree rotation (+/−90 degrees). Specifically, each motor wrist drive 116, 118 is capable of rotating from 90 degrees pitch up position as shown in dotted lines in FIG. 1 through 0 degrees horizontal position and down to 90 degrees pitch down position as shown dotted lines in FIG. 1. This range of motion allows improved clearance of end effector 102 from equipment obstacles. Motor wrist drives 116,118 each include a continuous position sensor (described below) as mentioned above for detecting forces and torques on a motor output shaft (horizontal or vertical) caused by inaccurate motion (i.e., position) of respective paddle assemblies 104,106. Motor wrist drives 116,118 are described in more detail below with respect to FIGS. 4-6.

Off axis compliance, paddle mounting and adjustment blocks 120,122 are constructed as off axis compliant paddle mount and adjustment blocks that mount (attach) paddle assemblies 104,106 to motor wrist drives 116,118, respectively. Off axis compliance, paddle mounting and adjustment blocks 120,122 are each bolted directly to the top of a universal mount (described below) of a paddle assembly. Each block includes two opposing L-shaped edges, each with one or more holes. Each block 120,122 is intended to bolt to various points (holes) along vertical edge of pitch axis interfaces (discussed below) of the motor wrist drives 116,118. The pitch of a paddle assembly is therefore adjusted (below motor wrist drive) by attaching a block to different points along the pitch axis interface of a motor wrist drive).

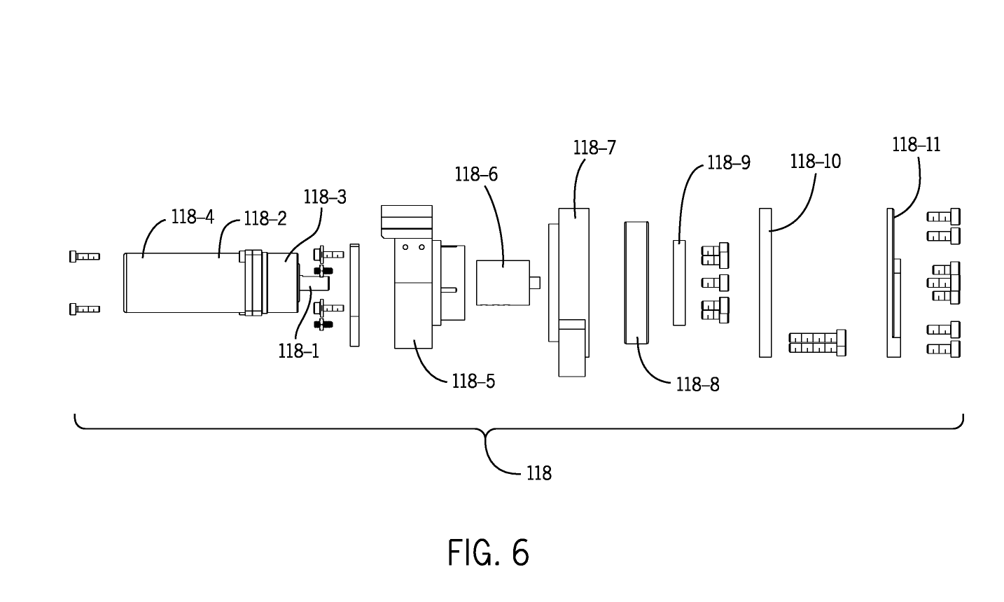

Motor drives controllers 124,126, one for each motor wrist drive 116,118, are mounted to the base of rotary union 110. (Motor drive controllers may also be referred to as drive controllers or controllers.) Motor drive controllers 124,126 are each typically a commercially available programmable single axis motion controller that incorporates a processor, memory and other components as known to those skilled in the art. Each controller 124,126 is initially programmed (coded) for each deployment to teach robot unit 108 and the motor inside respective motor wrist drive (116,118) the exact points where a respective paddle assembly (104,106) is meant to be located during the manufacturing process (for holding and transporting the disks). That is, controllers 124, 126 are programmed to move these respective assemblies to the proper locations to hold and transport the disks during the manufacturing process. (Redeployment may require reprogramming.) In operation, a continuous position sensor (118-4 of a motor wrist drive—FIG. 6 for example) will detect any force or torque on a motor output shaft by virtue of a discrepancy between the actual location of the motor output shaft 118-1 and its programmed location (118-1 of a motor wrist drive 118 for example) and send a signal to the respective controller of improperly programmed or subsequently altered programmed locations of a respective paddle assembly (104,106) during motion. Under the direction of a supervisory workcell control computer (not shown) the motor drive controller will automatically adjust and store those corrected points for future operation and movement of the paddle assembly (104,106).

FIG. 3 depicts an exploded unassembled view of rotary union 110 of the system 100 shown in FIG. 1. Rotary union 110 includes cap 110-1, top bearing housing ring 110-2, vacuum channel and seal housing rings 110-3, 110-4, bottom bearing cover ring 110-5, bearings 110-6, retaining ring 110-7, process vacuum ports 110-8, seals 110-9 and main frame 110-10. The rotary union 110 conveys all of the vacuum and electrical services from the robot to the various locations throughout the end effector 102. Process vacuum services enter through vacuum channel and seal housing rings 110-3, 110-4 and travel through process vacuum ports 110-8. Robot unit 108 extends through an opening in rotary union 110 until it reaches and is attached to main frame 110-10 of rotary union 110, thereby enabling main frame 110-10 to rotate independent of the other components of rotary union 110. As indicated above, main frame 110-10 delivers the process vacuum (via vacuum porting 110-8) and electrical services and scavenging vacuum to the other parts of end effector 102. While rotary union 110 configured as described above is preferred for its numerous benefits, those skilled in the art know that a commercially available rotary union can be employed to achieve desired results.

Reference is now made to FIGS. 4-5 wherein a perspective view of an example motor wrist drive 118 in FIG. 1 is depicted and a cross sectional view of motor wrist drive 118 in FIG. 1 taken along line 5-5 in FIG. 4 is depicted. FIG. 6 depicts an exploded view of motor wrist drive 118 in FIG. 1. (Motor wrist drive 116 has the same components and functions similarly.)

In particular, motor wrist drive 118 includes motor output shaft 118-1, pitch axis electric motor 118-2, gear reducer 118-3, continuous position sensor 118-4, motor housing 118-5, motor coupler 118-6, pitch axis interface 118-7, bearing set 118-8, inner race clamp plate 118-9, outer race clamp plate 118-10 and cover 118-11.

Pitch axis electric motor 118-2 is intended to rotate motor output shaft 118-1 via gear reducer 118-3. Pitch axis electric motor 118-2 may be a servo, stepper or other motor as known to those skilled in the art.

Gear reducer 118-3 functions to reduce the rotation of motor 118-2 into a usable rotation of motor output shaft 118-1 as known to those skilled in the art. (The shaft has an axis A (i.e., extends along an axis A) that is lateral to a longitudinal axis of an arm.)

Motor housing 118-5 functions to house the portion of the motor 118-2 and motor output shaft 118-1. Scavenging vacuum is applied to the motor housing via the ported arm to minimize contamination.

As described above, continuous position sensor 118-4 functions to sense (i.e., detect) the precise position of the motor output shaft and any deviation from a commanded position resulting from any force or torque on motor output shaft 118-1 transmitted from pitch axis interface 118-7 via motor coupler 118-6.

Pitch axis interface 118-7 is configured to rotate in response to rotation of drive shaft 118-1 through motor coupler 118-6, thereby causing attached paddle assembly 106 to pivot up or down as required for disk processing. Pitch axis interface 118-7 accommodates bearing set 118-8. Pitch axis interface 118-7 is attached to paddle assembly 106 as described in detail below.

Bearing set 118-8 enables the pitch axis interface 118-7 to rotate freely. Preloading bearing set 118-8 removes any lateral motion of the motor wrist assembly 118. Inner race clamp plate 118-9 preloads the inner race of bearing set 118-8 and outer race clamp plate 118-10 preloads the outer race of bearing set 118-8. Cover 118-11 attaches motor coupler 118-6 to the pitch axis interface 118-7 and encloses the bearing set to eliminate contamination. Bearing set 118-8 may be a commercially available component.

As indicated above, motor wrist drive 116 includes the same components and functions similarly as the motor wrist drive of assembly 118. While motor wrist drives 116,118 are shown in the figures and described herein, those skilled in the art know that any drive/mechanism may be used to pitch or move paddle assemblies 104,106 up or down (or other opposing directions) with respect to arms 112,114 (i.e., an axis defined by the arms 114,116). In addition, while dual arms 112,114, drives 116,118 and paddle assemblies 104,106 are described herein above and shown in FIGS. 1-7, those skilled in the art know that any number of arms, drives and corresponding paddle assemblies may be employed (e.g., one, two, three etc.) to achieve desired results.

End effector 102 as described above is designed to work with any paddle assembly known to those skilled in the art. Paddle assemblies 104,106 are example assembles that may be used with end effector 102. The operation of end effector 102 is now described with respect to paddle assemblies 104,106 but those skilled in the art know that other paddle assemblies may be employed. In operation, robot unit 108 moves to an input cassette housing one or more disks. End effector 102 pitches paddle assembly 104 to a vertical down position and a paddle assembly 106 to the horizontal position. Paddle assembly 104 extracts a first (unprocessed) disk from the input cassette. Robot unit 108 moves to a process machine. End effector 102 pitches paddle assembly 104 to a vertical up position. Paddle assembly 106 removes the finished disk from the process machine. In a coordinated sequence, robot unit 108 moves up vertically, paddle assembly 106 pitches to a vertically up position, paddle assembly 104 pitches to a horizontal position, end effector 102 rotates through an acute angle of typically 30 to 60 degrees as described above and robot unit 108 moves down to deposit (place) the unprocessed disk on the process machine. Robot unit 108 moves to an output cassette. Paddle assembly 106 pitches to a vertically down position and inserts the finished disk into the output cassette. Robot 108 moves to the input cassette and repeats this sequence.

In summary, end effector 102 described above has several advantages. First, the overall mass and size of end effector 102 is significantly small, thereby allowing robot 108 to move it its optimal speed and affording high system throughput. Second, motor wrist drives of end effector 102 each have a mass at the end thereof that is very low, allowing a small, lightweight and low power motor to be used. Third, the distance from each motor wrist drive 116,118 to the end of each paddle assembly 104,106 is short, with very few tolerance stack-ups. This ensures that paddle assembly (disk) position uncertainty is minimized. Fourth, the combination of continuous position sensor 118-4, electric motor 118-2 and controller 126 (or 124) allow for the precise control of the position/speed profile of the pitch motion of each paddle assembly throughout its range, thereby optimizing both speed and accuracy and minimize settling times of each pitch motion. Fifth, the combination of the continuous position sensor 118-4, electric motor 118-2, controller 126 (or 124) allow for the coordination and synchronization of pitch operations and robot unit 108 motion, thereby minimizing the disk exchange time at each process machine and increasing system throughput. Sixth, the integration of controllers 126,124 into the rotary union 110 minimizes the number of electrical wires that must be routed through robot unit 108 to end effector 102, thereby minimizing contamination, potential cable failures and system downtime. Seventh, the electrical connections between controllers 126 (or 124) and electric motors (e.g., 118-2) are fixed and stationary, thereby eliminating the possibility of cable failures and system downtime. Eighth, the rigid, stationary mechanical mounting of motor wrist drives 116,118 to ported arms 112,114 and the mounting of ported arms 112,114 to rotary union 110 minimize the mechanical tolerance build-ups of the end effector (assembly), thus assuring uniformity from one end effector 102 to another. Ninth, the particular arrangement of off axis compliance, paddle mounting and adjustment blocks 120,122 (off axis compliant paddle mount and adjustment blocks) allows continuous position sensor 118-4 to detect any resistance forces and torques that may be produced when placing or retrieving a disk from a process machine or cassette. Such built-in detection allows real-time, continuous and automatic adjustment of the precise coordinates of each location to which it moves with little or no human intervention. Lastly, off axis compliance, paddle mounting and adjustment blocks 120,122 allows for direct detecting (sensing) of many types of obstacles directly by continuous position sensor 118-4 therefore avoiding equipment damage and product loss.

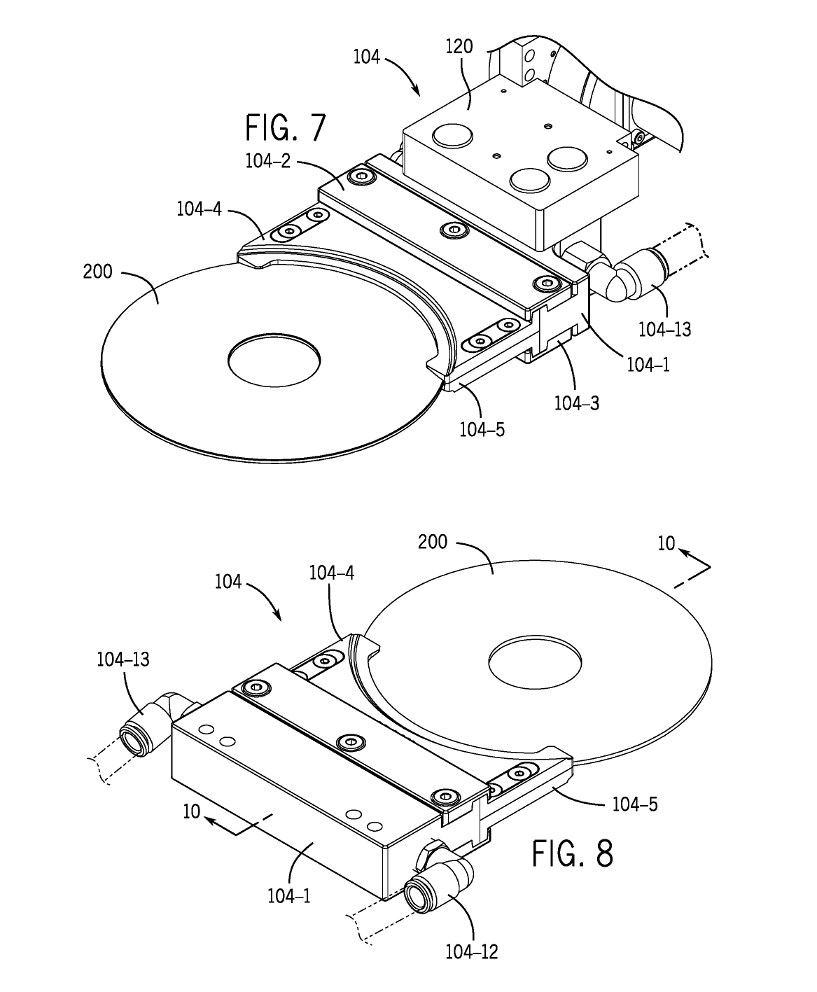

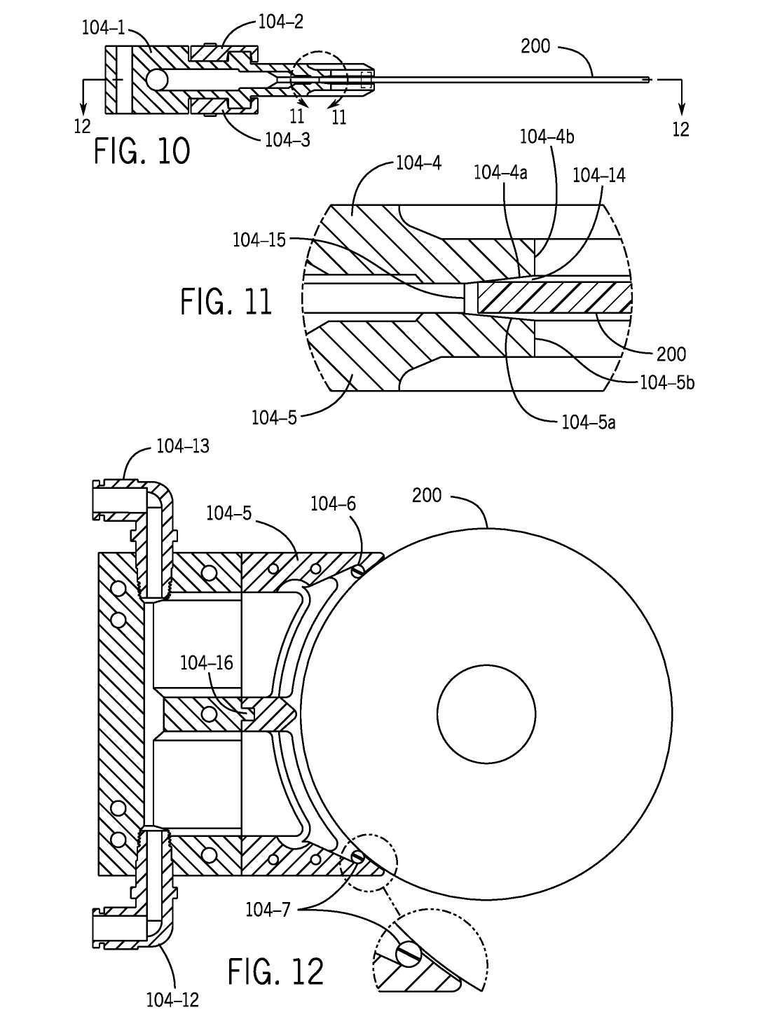

Embodiments of example paddle assemblies 104,106 are now described with respect to FIGS. 7-12. For purposes of this description below, paddle assembly 104 is described in detail but this description applies to paddle assembly 106 shown in the figures and described herein. In brief, paddle assembly 104 (assembly 106) is a multi-piece vacuum paddle assembly in which the portion that contacts a disk is split into two pieces along a plane parallel to the surface of the disk it grips. Many of the components of paddle assembly 104 are separately machined and then assembled, but those skilled in the art know that such components may be manufactured in a different manner.

Specifically, paddle assembly 104 comprises universal paddle mount 104-1, paddle clamps 104-2, 104-3, stub paddles or plates 104-4, 104-5, disk post pins 104-6, 104-7, lateral alignment pin (not shown), washer plates 104-8, 104-10, nut plates 104-9 and 104-11 and vacuum ports 104-12,104-13.

Universal paddle mount 104-1 (or paddle mount or mount) is used to mount paddle assembly 104 to motor wrist drive 116 by way of block 120. Paddle clamps 104-2,104-3 are used to attach and align two stub paddles or plates 104-4,104-5 to paddle mount 104-1. Paddle mount 104-1 and paddle clamps 104-2,104-3 are configured to be independent of disk form factor dimensions.

Plates 104-4,104-5, in an assembled configuration, together form a paddle that is configured to receive and hold (grasp) disk 200 for subsequent transportation. Specifically, plates 104-4, 104-5 include chamfer edges (walls) 104-4a, 104-5a that define groove 104-14 wherein disk 200 is seated. Groove 104-14 extends inwardly from curved peripheral edges or borders 104-4b, 104-5b (of plates 104-4 and 104-5) toward the rear of groove 104-14 as shown. This is best shown in FIG. 11. Groove 104-14 is configured with an angle sufficient to contact and hold disk 200. The inclination of the chamfer edges 104-4a, 104-5a (inclined edges or walls of groove) will generally decrease from curved peripheral border 104-4b, 104-5b inwardly toward the rear of groove 104-14 thereby defining an opening 104-15 that is employed to provide vacuum services from vacuum ports 104-12, 104-13 and connected cavities/channels as shown. Note, however, chamfer edges 104-4a, 104-5a (walls) within groove 104-14 may vary in slope as known to those skilled in the art to enable precise and proper contact with the rim of disk 200.

In practice, groove 104-14 is configured having a width slightly larger at the rear than the width of the disk. The rim of the disk typically makes contact with the top chamfer edge 104-4a only, as a result of gravity and vacuum application, thereby leaving a small space between the rim of the disk and chamfer edge 104-5a (adjacent the bottom rim of disk 200) as known to those skilled in the art. Registration is essentially one or more points of contact between disk 200 and chamfer edge 104-4a. It is this contact registration that controls the vertical position of disk 200 during transportation.

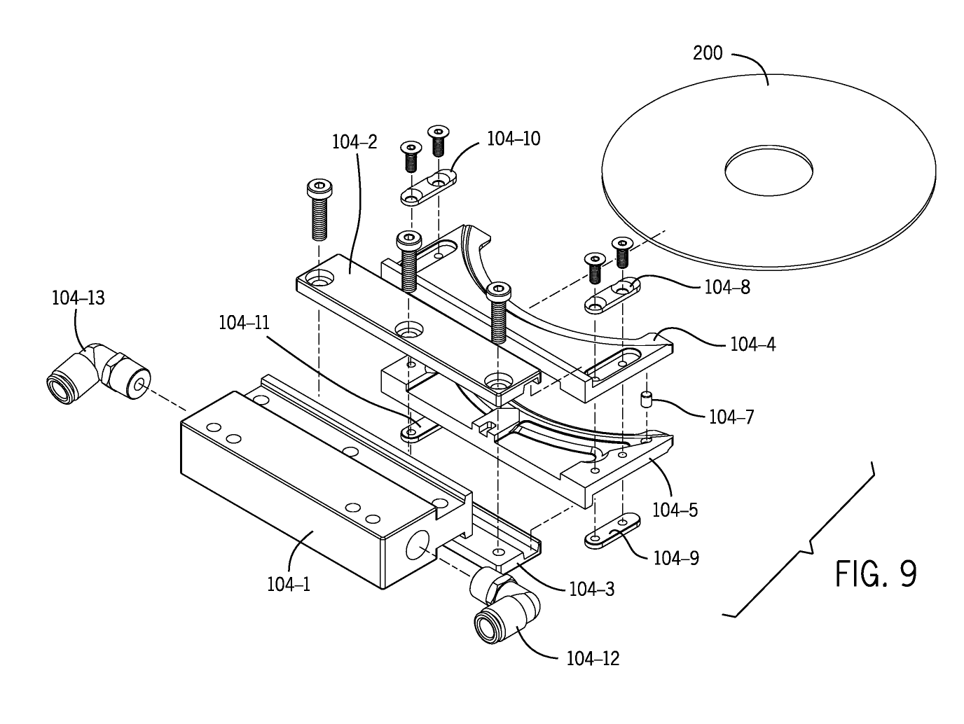

Disk post pins 104-6, 104-7 are positioned within the opposing triangular ends or tips of the paddle assembly between plates 104-4, 104-5 and adjacent groove 104-14. FIG. 9 depicts this configuration in an exploded view. FIG. 12 depicts the contact between disk 200 and pins 104-6,104-7. Note that disk 200 does not make contact with the actual tips of plates 104-4 and 104-5. There is a small gap or space between the outer diameter of disk 200 and the triangular tips of plates 104-4 and 104-5. In full advanced position, disk 200 makes contact with pins 104-6, 104-7 and at least one point along chamfer edge 104-4a.

Disk post pins 104-6,104-7 are configured to ensure precise and repeatable horizontal alignment of disk 200 within the groove defined by chamfer edges 104-4a, 104-5a of plates 104-4,104-5. That is, disk post pins 104-6,104-7 guide disk 200 so that it engages and seats with groove 104-14 properly. In short, pins 104-6, 1-4-7 control the horizontal position of disk 200 within the groove. Disk post pins 104-6, 104-7 also ensure the precise and repeatable horizontal alignment of the two plates 104-5, 104-6 when assembled and mounted to the universal paddle mount 104-1.

In sum, it is this contact registration described above (i.e., contact with pins 14-6, 104-7 and one or more points on edge 104-4a of groove 104-14) that controls both the vertical and horizontal position of disk 200 during transportation. In this respect, disk 200 is not damaged or contaminated by the contact registration.

Lateral alignment pin 104-16, washer plates 104-8, 104-10 and nut plates 104-9,104-11 are configured to assist in proper assembly and alignment of paddles 104-4,104-5. Three pins are described herein and shown in the figures, but those skilled in the art know that any number of pins may be used to achieve desired results.

Vacuum ports (pipes) 104-12,104-13 provide vacuum services from vacuum pipes on ported arms 112,114 (e.g., vacuum pipe 114-2). The vacuum services or suction maintain disk 200 in place within the groove described above.

The components of the paddle assemblies 104,106 may be constructed with a variety of materials such as various conductive and static dissipative plastic compounds, aluminum and stainless steel.

As described above, the same components and functionality of paddle assembly 104 are part of paddle assembly 106.

Paddle assemblies 104,106 have several advantages. First, these paddle assemblies reduce disk contamination by decreasing sliding contact and/or reducing airborne particles. Second, the plates can be removed, disassembled, cleaned and inspected in great detail. Worn and damaged parts can be easily replaced without incurring excessive production down time for adjusting programmed positions and end effector alignment and calibration. Further, individual components are less expensive to replace. Third, disk outer diameter damage is reduced. Fourth, dividing a vacuum paddle into two plates exposes all inner surfaces, thereby making machining and deburring easier with the ability to hold very tight tolerances as compared to current designs. Fifth, all critical dimensions of the paddle assembly and especially its interior are precisely controlled and are readily measured to determine compliance with design specifications. Sixth, the dimensions and contours of the groove (defined by the stub paddles) and the interior of the assembled paddle are varied along the circumference of the groove to minimize the contact area between the paddle and the disk. Seventh, the width of the groove is precisely controlled to maximize the paddle's holding power of the disks during high dynamic loads. Eighth, abrasion between the surface of the disk and the paddle is minimized and as a result contamination is reduced. And finally, surface contact between the body of the paddle and the surfaces of the disk is significantly reduced or eliminated.

While the embodiments of apparatus 102 and assemblies 104,106 described above involve disks, apparatus 102 and paddle assemblies 104,106 may also be used holding and transporting objects that are circular and flat that require fast, efficient and low cost and/or low contamination handling.

It is to be understood that the disclosure teaches examples of the illustrative embodiments and that many variations of the invention can easily be devised by those skilled in the art after reading this disclosure and that the scope of the present invention is to be determined by the claim(s) below.

What is claimed is:

1. A paddle assembly for holding an object, the paddle assembly comprising:
a first plate and a second plate, together forming a paddle having a longitudinal axis and defining a groove configured to engage the object on a peripheral edge thereof and seat the object along the longitudinal axis; and
a first pin between the first and second plates adjacent the groove, the first pin configured to align the object within the groove along the longitudinal axis.

2. The paddle assembly of claim 1 further comprising a second pin between the first and second plates adjacent the groove, the second pin configured to align the object within the groove along the longitudinal axis.

3. The paddle assembly of claim 1 further comprising a mount configured to mount the first and second plates to an end effector.

4. The paddle assembly of claim 1 wherein the first plate includes a chamfer edge and the second plate includes a chamfer edge, the chamfer edges of the first and second plates together define the groove.

5. The paddle assembly of claim 1 wherein the chamfer edges that define the groove create an angle sufficient to hold the object at lease one point of contact along a chamfer edge.

6. The paddle assembly of claim 3 further comprising first and second clamps configured to attach the first and second plates to the mount.

7. The paddle assembly of claim 1 wherein the object is a disk, wafer, substrate or other round, flat object.

8. A paddle assembly for holding an object having a peripheral edge that defines a radius of the object, the paddle assembly comprising:
a first plate and a second plate opposing the first plate, the first plate and second plate together form a paddle having a longitudinal axis and configured to engage the object,
wherein the first plate includes a chamfer edge and the second plate includes a chamfer edge, the chamfer edges of the first and second plates together define a groove configured to engage the object on the peripheral edge thereof and seat the object along the longitudinal axis; and
a mount configured to mount the first and second plates to an end effector.

9. The paddle assembly of claim 8 wherein the first and second chamfer edges define a width that decreases at the periphery of the first and second plates toward a rear of the groove.

10. The paddle assembly of claim 9 wherein the width is greater than a width of the disk.

11. The paddle assembly of claim 8 further comprising first and second pins between the first and second plates adjacent the groove, the first and second pins configured to align the object within the groove along the longitudinal axis.

12. The paddle assembly of claim 8 further comprising first and second clamps configured to attach the first and second plates to the mount.

13. The paddle assembly of claim 8 wherein the object is a disk.

14. The paddle assembly of claim 8 wherein the first and second plates together form a paddle that define one or more channels configured to receive vacuum services to maintain the object within the groove.

15. A system for processing disks during manufacture, the system comprising:
an apparatus for transporting a disk from one location to another location within a manufacturing environment; and
a paddle assembly attached to the apparatus, the paddle assembly comprising a first plate and a second plate, together forming a paddle having a longitudinal axis and defining a groove configured to engage the object on a peripheral edge thereof and seat the object along the longitudinal axis; and
a first pin between the first and second plates adjacent the groove, the first pin configured to align the object within the groove along the longitudinal axis.

16. The paddle assembly of claim 15 further comprising a second pin between the first and second plates adjacent the groove, the second pin configured to align the object within the groove along the longitudinal axis.

17. The paddle assembly of claim 15 further comprising a mount configured to mount the first and second plates to an end effector.

18. The paddle assembly of claim 15 wherein the first plate includes a chamfer edge and the second plate includes a chamfer edge, the chamfer edges of the first and second plates together define the groove.

19. A system for processing disks during manufacture, the system comprising:
an apparatus for transporting a disk from one location to another location; and
a paddle assembly for hold a disk for transportation of the disk, wherein the paddle assembly comprising:
a first plate and a second plate opposing the first plate, the first plate and second plate together form a paddle having a longitudinal axis and configured to engage the object,
wherein the first plate includes a chamfer edge and the second plate includes a chamfer edge, the chamfer edges of the first and second plates together define a groove configured to hold the object on the peripheral edge thereof and seat the object along the longitudinal axis; and
a mount configured to support the first and second plates.

20. The paddle assembly of claim 19 further comprising first and second pins between the first and second plates within the groove, the first and second pins configured to align the object within the groove along the longitudinal axis.

21. A paddle assembly for holding an object during manufacture, the paddle assembly comprising:
a first plate and a second plate, together forming a paddle having a longitudinal axis and defining a groove configured to engage the object on a peripheral edge thereof and seat the object along the longitudinal axis, wherein the groove includes first and second inclined edges at least one of which engages the peripheral edge of the object.
